(19) United States
(12) Patent Application Publication
(10) Pub. No.: US 2011/0309152 A1
(43) Pub. Date: Dec. 22, 2011

(54) PLASTIC CARD PACKAGE AND PLASTIC CARD PACKAGE MANUFACTURING METHOD

(76) Inventor: Young-Sun KIM, Seoul (KR)

(21) Appl. No.: 12/950,467

(22) Filed: Nov. 19, 2010

(30) Foreign Application Priority Data
Jun. 22, 2010 (KR) 10-2010-0059118

(51) Int. Cl. G06K 19/077; G06F 17/00; H01L 21/50

(52) U.S. Cl. 235/492; 438/107; 700/121; 257/E21.499

(57) ABSTRACT

A plastic card package and a method of manufacturing the plastic card package are provided. The plastic card package includes: a socket insertion area that is formed to expose an I/O terminal corresponding to a contact terminal of a socket electrically connected to a printed circuit board of an electronic apparatus; and a socket non-insertion area that horizontally extends from the socket insertion area and has a thickness greater than that of the socket insertion area. Accordingly, it is possible to cause the plastic card to have different thicknesses by areas so as to stably built a semiconductor chip therein and to stably mount stacked semiconductor chips thereon.

### CROSS REFERENCE

This application is based on and claims priority under 35 USC 119 from Korean Patent Application No. 10-2010-0059118, filed on Jun. 22, 2010.

### BACKGROUND

1. Field of the Invention

The present invention relates to a plastic card package and a plastic card package manufacturing method, and more particularly, to a plastic card package which is mounted on a socket so as to serve as a subscriber identification module and a plastic card package manufacturing method.

2. Description of the Related Art

A GSM (Global System for Mobile Communication) system, a TDMA (Time Division Multiple Access) system, a CDMA (Code Division Multiple Access) system, and the like can be used for mobile wireless terminals. In the GSM system used in Europe, a SIM card which is an IC card having a subscriber identification module (SIM) therein to identify a user of a mobile wireless terminal is basically employed.

The SIM card is generally introduced in the foam of a USIM (Universal SIM) card into countries employing the CDMA communication system with the start of a three-generation mobile communication service.

The plastic cards such as the SIM card and the USIM card store personal information, the phone number, and network information of a subscriber and are standardized in a size of 85.60 mm×53.98 mm×0.76 mm and a size of 25 mm×15 mm×0.76 mm.

FIGS. 1A and 1B are diagrams illustrating an example of a plastic card according to the related art. FIG. 1A is a plan view of the plastic card and FIG. 1B is a side view (a sectional view taken along line A-B) of the plastic card.

As shown in FIGS. 1A and 1B, the plastic card 100 has a package shape standardized to be flat and has a small thickness of about 0.76 mm, which serves as a restriction factor in mounting semiconductor chips or passive components on the package.

With the recent functional improvement of smart phones, it is necessary to stack and mount plural semiconductor chips on the plastic card 100.

Therefore, there is a need for a method for increasing the thickness up to a proper level sufficient to stably mount the semiconductor chips at the time of manufacturing a SIM card package.

### SUMMARY

An advantage of some aspects of the invention is that it provides a plastic card package which has various thicknesses by areas so as to stably built a semiconductor chip therein and to stably mount stacked semiconductor chips thereon, and a plastic card package manufacturing method.

Another advantage of some aspects of the invention is that it provides a plastic card package which can guarantee a space for mounting an additional semiconductor chip in a plastic card package, and a plastic card package manufacturing method.

Another advantage of some aspects of the invention is that it provides a plastic card package which has an increased thickness in a partial area of a plastic card so as to stably mount a semiconductor chip thereon and to improve the reliability and the production yield of the plastic card, and a plastic card package manufacturing method.

Another advantage of some aspects of the invention is that it provides a plastic card package which can easily mount and demount a plastic card on and from a socket (connector), and a plastic card package manufacturing method.

Other advantages of the invention will be easily understood from the following description.

According to an aspect of the invention, there is provided a plastic card package including: a socket insertion area that is formed to expose an I/O terminal corresponding to a contact terminal of a socket electrically connected to a printed circuit board of an electronic apparatus; and a socket non-insertion area that horizontally extends from the socket insertion area and has a thickness greater than that of the socket insertion area.

The socket insertion area and the socket non-insertion area may be formed to have a step difference using a mold die and an epoxy mold compound.

The socket insertion area and the socket non-insertion area may be formed to have a step difference using different numbers of plastic sheets or plastic sheets with different thicknesses.

A structure giving a frictional force may be formed on the top surface of the socket non-insertion area.

The structure giving a frictional force may be an unevenly-patterned structure.

The structure giving a frictional force may be formed by applying or attaching a material with a surface roughness to the top surface of the socket non-insertion area.

The plastic card package may be one or more of a SIM card package and a USIM card package.

According to another aspect of the invention, there is provided a plastic card package manufacturing method in which a plastic card package is electrically connected to a printed circuit board of an electronic apparatus through a socket, including the steps of: mounting one or more semiconductor chips and elements on a board; electrically connecting the semiconductor chips and elements to the board; and forming a body portion so that a socket insertion area of which an I/O terminal corresponding to a contact terminal of the socket is exposed and a socket non-insertion area which horizontally extends from the socket insertion area have a step difference.

The step of forming a body portion may include causing the socket insertion area and the socket non-insertion area to have a step difference using a mold die and an epoxy mold compound.

The step of forming a body portion may include causing the socket insertion area and the socket non-insertion area to have a step difference using different numbers of plastic sheets or plastic sheets with different thicknesses.

The plastic card package manufacturing method may further include a step of forming a structure giving a frictional force on the top surface of the socket non-insertion area.

The structure giving a frictional force may be an unevenly-patterned structure.

The structure giving a frictional force may be formed by applying or attaching a material with a surface roughness to the top surface of the socket non-insertion area.

Other aspects, features, and advantages will become apparent from the accompanying drawings, the appended claims, and the detailed description.

According to the above-mentioned aspects of the invention, it is possible to make the plastic card have various thicknesses by areas so as to stably built a semiconductor chip therein and to stably mount stacked semiconductor chips thereon.

It is also possible to guarantee a space for mounting an additional semiconductor chip in a plastic card package.

It is also possible to increase the thickness in a partial area of a plastic card so as to stably mount a semiconductor chip thereon and to improve the reliability and the production yield of the plastic card.

It is also possible to easily mount and demount a plastic card on and from a socket (connector).

### BRIEF DESCRIPTION OF THE DRAWINGS

FIGS. 1A and 1B are diagrams illustrating an example of a known plastic card.

FIG. 2 is diagram illustrating an example of a plastic card according to an embodiment of the invention.

FIGS. 3A and 3B are diagrams illustrating a sectional configuration of the plastic card according to the embodiment of the invention.

FIGS. 4A to 4C are diagrams illustrating a plastic card manufacturing method according to an embodiment of the invention.

FIG. 5 is a diagram illustrating a sectional configuration of a plastic card according to another embodiment of the invention.

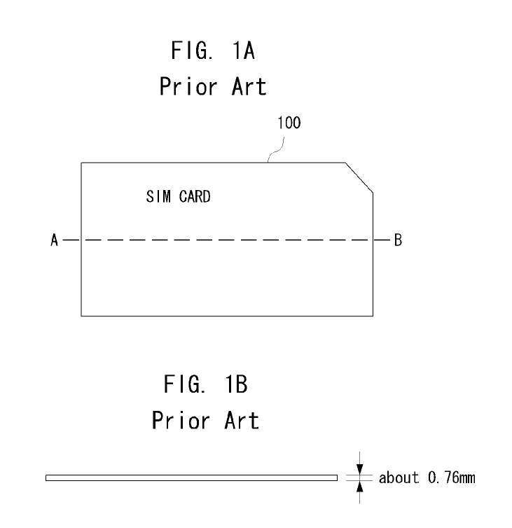

### DESCRIPTION OF EXEMPLARY EMBODIMENTS

The invention can be variously modified in various forms and specific embodiments will be described and shown in the drawings. However, the embodiments are not intended to limit the invention, but it should be understood that the invention includes all the modifications, equivalents, and replacements belonging to the spirit and the technical scope of the invention.

If it is mentioned that an element is “connected to” or “coupled to” another element, it should be understood that still another element may be interposed therebetween, as well as that the element may be connected or coupled directly to another element. On the contrary, if it is mentioned that an element is “connected directly to” or “coupled directly to” another element, it should be understood that still another element is not interposed therebetween.

The terms used in the following description are used to merely describe specific embodiments, but are not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

In describing the invention with reference to the accompanying drawings, like elements are referenced by like reference numerals regardless of the drawing numbers and repeated description is not made. When it is determined that detailed description of known techniques associated with the invention makes the gist of the invention obscure, the detailed description will be omitted.

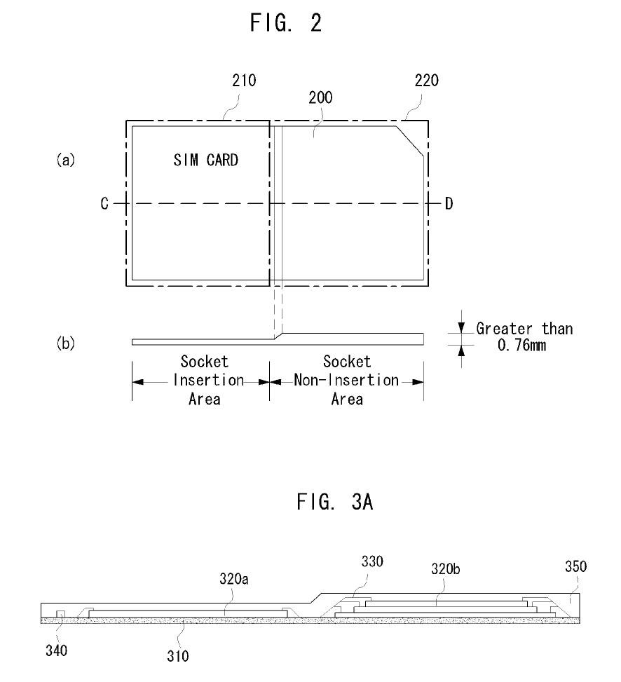

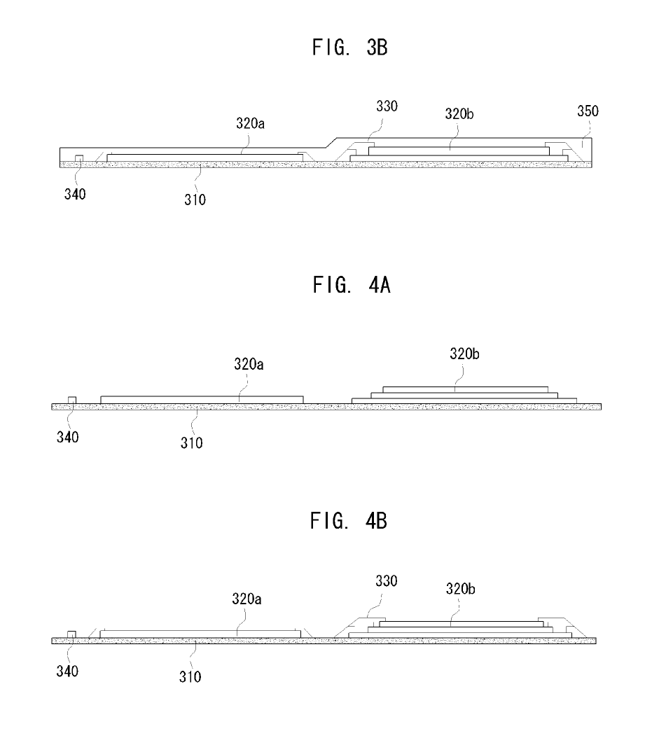

FIG. 2 is diagram illustrating an example of a plastic card according to an embodiment of the invention. FIGS. 3A and 3B are diagrams illustrating a sectional configuration of the plastic card according to the embodiment of the invention.

Referring to (a) of FIG. 2 which is a plan view of a plastic card 200, the planar shape of the plastic card 200 according to this embodiment is formed equal or similar to the known plastic card 100.

However, referring to (b) of FIG. 2 which is a side view (a sectional view taken along line C-D) of the plastic card 200, the plastic card 200 is divided into a socket insertion area 210 which is inserted into a socket (connector) and a socket non-insertion area 220 which is not inserted into the socket. The socket is a connector electrically connecting the plastic card 200 to a PCB (a main board or the like) of an electronic apparatus to be mounted with the plastic card 200. In general, the plastic card (such as a SIM card and a USIM card) is pressed and inserted into the socket connected to the PCB, where the socket has such a size to receive a portion (for example, substantially a half of the plastic hard) of the plastic card in which an I/O (Input/Output) terminal is formed. That is, the I/O terminal is exposed and formed in the socket insertion area 210 to correspond to a contact terminal of the socket and is electrically connected to the PCB of the electronic apparatus.

The socket insertion area 210 has a thickness corresponding to the thickness of the socket into which the plastic card 200 is inserted. For example, the thickness is equal to the thickness of the known plastic card 100 within an error range. However, the socket non-insertion area 220 has a thickness greater than that of the socket insertion area 210 so that a semiconductor chip is stably mounted thereon and/or the plastic card is easily mounted one and demounted from the socket.

As shown in FIG. 2 and FIGS. 3A and 3B, the socket insertion area 210 and the socket non-insertion area 220 have different thicknesses so as to have a step and the socket non-insertion area 220 is relatively thick.

The semiconductor chip which was mounted on the known plastic card 100 can be mounted on the socket insertion area 210. The socket non-insertion area 220 has a thickness greater than that of the known plastic card 100 and can be mounted with plural semiconductor chips stacked vertically or with plural semiconductor chips arranged in horizontally.

Various semiconductor chips can be mounted on the plastic card 200 depending on the application of the plastic card 200 and examples thereof include a multimedia processor chip, a communication chip, and a memory chip.

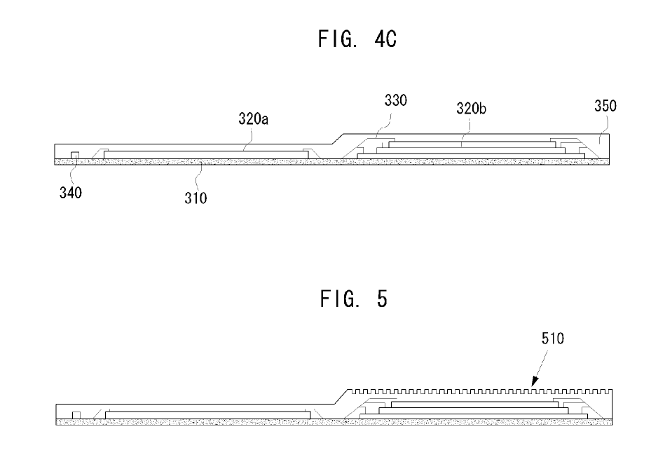

FIGS. 4A to 4C are diagrams illustrating a method of manufacturing a plastic card according to an embodiment of the invention.

Referring to FIG. 4A, semiconductor chips 320a and 320b and elements 340 such as a capacitive element, a resistive element, and a coil are mounted on a board 310 for the plastic card 310. The semiconductor chips 320a and 320b and the elements 340 can be mounted on the board 310, for example, using an adhesive. For example, the board 310 may be a printed circuit board (PCB).

As shown in FIG. 4B, I/O terminals of the semiconductor chips 320a and 320b are connected to I/O terminals of the board 310 using metal wires 330. The metal wires 330 are formed of, for example, gold or aluminum. As the method of connecting the semiconductor chips 320a and 320b to the board 310, various methods such as a wire bonding method and a flip-chip bonding method can be used.

As shown in FIG. 4C, a molding process is performed using a mold die and a epoxy mold compound 350 to form the plastic card in a stair shape having a step difference.

In manufacturing the plastic card 200, a method of stacking plastic sheets and thermally pressing the stacked plastic sheets may be used as well as the molding method using the mold die.

That is, a space for mounting the semiconductor chips 320a and 320b is formed in a plastic sheet and then the socket insertion area 210 and the socket non-insertion area 220 are formed to have different thicknesses using different number of plastic sheets which are stacked in the socket insertion area 210 and the socket non-insertion area 220 or using plastic sheets with different thicknesses which are stacked in the areas.

FIG. 5 is a sectional view of a plastic card according to another embodiment of the invention.

In order to cause a user to easily mount and demount the plastic card 200 on and from the socket, a structure 510 having a frictional force against a user's finger or finger tip is formed on the top surface of the socket non-insertion area 220.

The structure giving a frictional force may be an uneven pattern as shown in FIG. 5. The uneven pattern can be formed in a part or all of the socket non-insertion area 220. The user can easily insert or demount the plastic card into and from the socket by bringing the finger tip in contact with the uneven pattern.

In order to give a frictional force, a material with a surface roughness may be applied or attached to the surface of the socket non-insertion area 220.

As described above, a plastic card with a standard size of a very small thickness has a difficulty in mounting a large number of semiconductor chips thereon. To solve this difficulty, it has been tried to form semiconductor chips out of a very thin wafer and to mount the formed semiconductor chips on a plastic card. However, the method of forming semiconductor chips out of a very thin wafer causes a low reliability of the semiconductor chips due to the small thickness of the wafer and a low yield due to a high failure ratio.

On the contrary, the plastic card having a step difference according to the embodiments of the invention can guarantee the thickness sufficient to mount the semiconductor chips, thereby guaranteeing the reliability of the semiconductor chips and the high yield due to the decrease in failure ratio.

The above-mentioned plastic card package manufacturing method may be carried out in time series by a software program built in an operation device. Codes and code segments of the program will be easily obtained by programmers skilled in the art. The program can be stored in a computer-readable recording medium and can be read and executed by a computer to embody the above-mentioned methods. The recording medium includes a magnetic recording medium, an optical recording medium, and a carrier wave medium.

While the invention has been described with reference to the exemplary embodiments, it will be understood by those skilled in the art that the invention can be modified and changed in various forms without departing from the spirit and scope of the invention described in the appended claims.

What is claimed is:

1. A plastic card package comprising:
a socket insertion area that is formed to expose an I/O terminal corresponding to a contact terminal of a socket electrically connected to a printed circuit board of an electronic apparatus; and
a socket non-insertion area that horizontally extends from the socket insertion area and has a thickness greater than that of the socket insertion area.

2. The plastic card package according to claim 1, wherein the socket insertion area and the socket non-insertion area are formed to have a step difference using a mold die and an epoxy mold compound.

3. The plastic card package according to claim 1, wherein the socket insertion area and the socket non-insertion area are formed to have a step difference using different numbers of plastic sheets or plastic sheets with different thicknesses.

4. The plastic card package according to claim 1, wherein a structure giving a frictional force is formed on the top surface of the socket non-insertion area.

5. The plastic card package according to claim 4, wherein the structure giving a frictional force is an unevenly-patterned structure.

6. The plastic card package according to claim 4, wherein the structure giving a frictional force is formed by applying or attaching a material with a surface roughness to the top surface of the socket non-insertion area.

7. The plastic card package according to claim 1, wherein the plastic card package is one or more of a SIM card package and a USIM card package.

8. A plastic card package manufacturing method in which a plastic card package is electrically connected to a printed circuit board of an electronic apparatus through a socket, comprising:
mounting one or more semiconductor chips and elements on a board;
electrically connecting the semiconductor chips and elements to the board; and
forming a body portion so that a socket insertion area of which an I/O terminal corresponding to a contact terminal of the socket is exposed and a socket non-insertion area which horizontally extends from the socket insertion area have a step difference.

9. The plastic card package manufacturing method according to claim 8, wherein the step of forming a body portion includes causing the socket insertion area and the socket non-insertion area to have a step difference using a mold die and an epoxy mold compound.

10. The plastic card package manufacturing method according to claim 8, wherein the step of forming a body portion includes causing the socket insertion area and the socket non-insertion area to have a step difference using different numbers of plastic sheets or plastic sheets with different thicknesses.

11. The plastic card package manufacturing method according to claim 8, further comprising a step of forming a structure giving a frictional force on the top surface of the socket non-insertion area.

12. The plastic card package manufacturing method according to claim 11, wherein the structure giving a frictional force is an unevenly-patterned structure.

13. The plastic card package manufacturing method according to claim 11, wherein the structure giving a frictional force is formed by applying or attaching a material with a surface roughness to the top surface of the socket non-insertion area.

14. A recording medium having recorded thereon a program which can be read by a digital processor and in which command words executable by the digital processor are materially described so as to carry out the plastic card package manufacturing method according to claim 8.
